(19) United States
(12) Patent Application Publication
(10) Pub. No.: US 2007/0262370 A1
(43) Pub. Date: Nov. 15, 2007

(54) SEMICONDUCTOR DEVICE

(75) Inventor: Norio Okada, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/745,650

(22) Filed: May 8, 2007

(30) Foreign Application Priority Data
May 10, 2006 (JP) 2006-131610

(51) Int. Cl. H01L 29/788

(52) U.S. Cl. 257/315

(57) ABSTRACT

In an interface between different interlayer insulating films formed of different insulating materials, a flaking-off of the film is easily created, as compared with an interface between interlayer insulating films formed of a same insulating material. A semiconductor device 1 includes a semiconductor substrate 10, an interlayer insulating film 20 (first interlayer insulating film), an interlayer insulating film 30 (second interlayer insulating film) and an interconnect structure 40. The interlayer insulating film 20 is provided on the semiconductor substrate 10. The interlayer insulating film 20 is formed of a first insulating material. The interlayer insulating film 30 is provided on the interlayer insulating film 20. The interlayer insulating film 30 is formed of a second insulating material. Here, the first and the second insulating materials are different insulating materials.

The interconnect structure 40 is formed in the circumference region of the semiconductor device 1. The interconnect structure 40 is configured to include an electroconducting plug, and extends through the interface of the interlayer insulating film 20 and the interlayer insulating film 30.

This application is based on Japanese patent application No. 2006-131,610, the content of which is incorporated hereinto by reference.

### BACKGROUND

1. Technical Field

The present invention relates to a semiconductor device.

2. Related Art

In a manufacture of a semiconductor device, a wafer having predetermined circuits composed of transistors or the like formed therein is diced to obtain discrete semiconductor chips. Nonetheless, a chipping or a flaking-off of an interlayer insulating film is often caused during the dicing process. Conventionally, an appearance-viewing by employing an optical microscope was performed for respective semiconductor chips after the dicing process, in order to detect such chipping and flaking-off of the interlayer insulating film.

However, according to an enlarged wafer diameter and a reduced chip size, it is difficult to conduct one hundred percent inspection due to a limitation in the process time. Further, although a chipping is generated, such chipping can not be often detected due to a limited resolution of an optical microscope.

Under such circumstances, semiconductor chips that are capable of electrically detecting cracks created after the dicing process are disclosed in Japanese Patent Laid-Open No. H7-193,108 (1995), Japanese Patent Laid-Open No. 2000-31,230 and Japanese Patent Laid-Open No. 2005-277,338. In these patent applications, electrically conducting layers such as interconnects and the like are provided in circumference portions of semiconductor chips. When a crack is generated in a semiconductor chip, an electrically conducting layer therein is broken, so that a creation of a crack can be detected in a form of a change in electricity.

Meanwhile, in recent years, an interlayer insulating film is often formed of different insulating materials, which are separately employed for constituting a lower layer section and an upper layer section, respectively. For example, concerning the upper layer section, which includes interconnects having relatively long interconnect distance and thus is easily affected by a parasitic capacitance, an insulating material having lower dielectric constant than that of the lower layer section, such as low dielectric constant material and the like, may be often employed for reducing parasitic capacitance.

In an interface between different interlayer insulating films formed of different insulating materials, a flaking-off of the film is easily created, as compared with an interface between interlayer insulating films formed of a same insulating material. Therefore, in a semiconductor device including a plurality of interlayer insulating films formed of different insulating materials, a detection of a flaking-off generated in the interface between the interlayer insulating films during the dicing process is required with higher detecting accuracy.

### SUMMARY

According to one aspect of the present invention, there is provided a semiconductor device having a region for forming an electric circuit, comprising: a semiconductor substrate; a first interlayer insulating film, provided on the semiconductor substrate and formed of a first insulating material; a second interlayer insulating film, provided on the first interlayer insulating film and formed of a second insulating material, which is different from the first insulating material; and an interconnect structure, provided in the outside of the region for forming an electric circuit and configured to include an electroconducting plug, wherein the interconnect structure extends through an interface of the first interlayer insulating film and the second interlayer insulating film.

In such semiconductor device, an interconnect structure for sensing a flaking-off is provided in the outside of the region for forming an electric circuit. Further, such interconnect structure for sensing a flaking-off extends through the interface of the first and the second interlayer insulating films, which are formed of different insulating materials. Thus, when a flaking-off is generated in the interface to cause a crack and/or a breaking is created in the interconnect structure for sensing a flaking-off, such flaking-off can be converted into a change in characteristics of electricity caused in the interconnect structure for sensing a flaking-off. Therefore, even if a flaking of is generated in the above-described interface during the dicing process or the like, a detection of a change in the electric characteristics caused in the interconnect structure allows detecting the flaking-off with higher accuracy.

According to the present invention, a semiconductor device, which is capable of detecting a flaking-off caused in the interface between the different interlayer insulating films composed of different insulating materials with higher accuracy, is achieved.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view, showing an embodiment of a semiconductor device according to the present invention;

FIG. 2 is a cross-sectional view, showing a cross section along line A-A′ of FIG. 1;

FIG. 3 is a cross-sectional view, showing a cross section along line B-B′ of FIG. 1;

FIG. 4 is a cross-sectional view, showing a cross section along line C-C′ of FIG. 3;

FIG. 5 is a cross-sectional view, showing a cross section along line D-D′ of FIG. 1;

FIG. 6 is a cross-sectional view, showing a semiconductor device according to a modified version of an embodiment;

FIG. 7 is a cross-sectional view, showing a semiconductor device according to another modified version of an embodiment;

FIG. 8 is a cross-sectional view, showing another semiconductor device according to further modified version of an embodiment; and

FIG. 9 is a plan view, showing another semiconductor device according to yet other modified version of an embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed Exemplary implementations of semiconductor devices according to the present invention will be described in reference to the annexed figures. In all figures, identical numeral is assigned to an element commonly appeared in both of the description of the present invention the description of the related art, and the detailed description thereof will not be repeated.

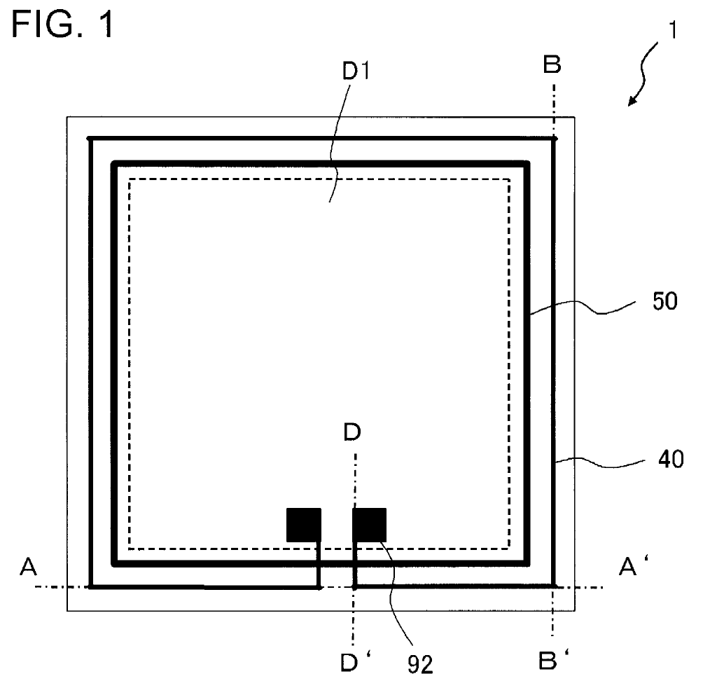

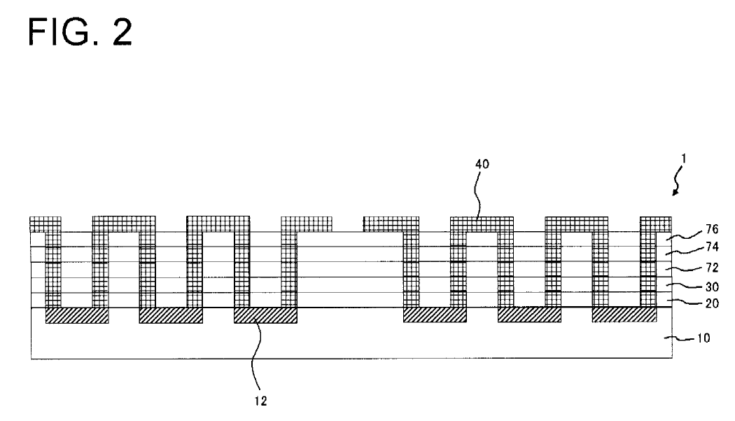

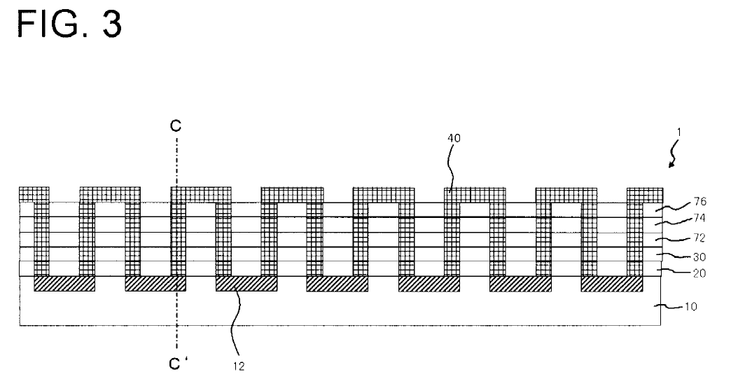

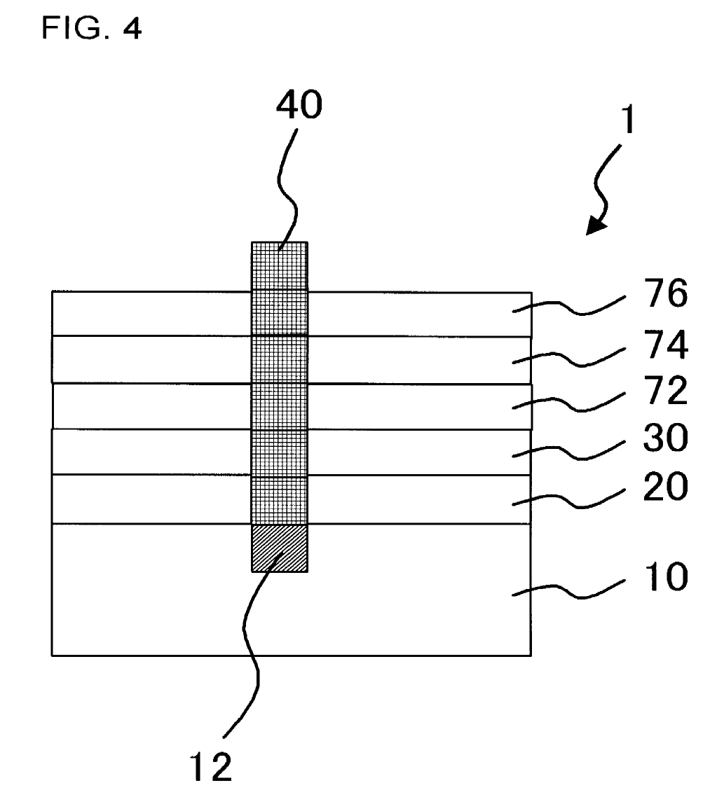

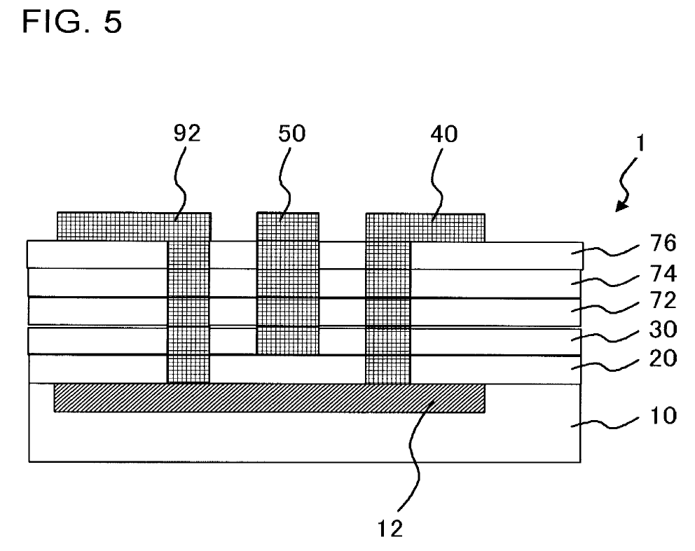

FIG. 1 is a plan view, showing a first embodiment of a semiconductor device of the present invention. FIG. 2 is a cross-sectional view, showing a cross section along line A-A′ of FIG. 1. FIG. 3 is a cross-sectional view, showing a cross section along line B-B′ of FIG. 1. FIG. 4 is a cross-sectional view, showing a cross section along line C-C′ of FIG. 3. FIG. 5 is a cross-sectional view, showing a cross section along line D-D′ of FIG. 1.

A semiconductor device 1 includes a semiconductor substrate 10, an interlayer insulating film 20 (first interlayer insulating film), an interlayer insulating film 30 (second interlayer insulating film) and an interconnect structure 40. The semiconductor substrate 10 is, for example, a silicon substrate.

The interlayer insulating film 20 is provided on the semiconductor substrate 10. The interlayer insulating film 20 is formed of a first insulating material. The interlayer insulating film 30 is provided on the interlayer insulating film 20. The interlayer insulating film 30 is formed of a second insulating material. Here, the first and the second insulating materials are different insulating materials. In the present embodiment, the first and the second insulating materials have different dielectric constants. The first and the second insulating materials are, for example, silicon oxide and a low dielectric constant material, respectively.

The low dielectric constant material is an insulating material having a specific dielectric constant of lower than 3.3. Typical low dielectric constant materials include variety of compounds of, for example: polyorganosiloxanes such as silicon oxycarbide (SiOC), hydrogen silsesquioxane (HSQ), methyl silsesquioxane (MSQ), methylated hydrogen silsesquioxane (MHSQ) and the like; aromatic compound-containing organic materials such as polyarylether (PAE), divinylsiloxane-bis-benzo cyclobutene (BCB), Silk^{TR} (commercially available from Hitachi Chemical Co., Ltd., Tokyo Japan) and the like; spin-on glass (SOC), FOX^{TR} (flowable-oxide, commercially available from Dow-Corning, Midland, Mich. USA). Alternatively, a porous material may also be employed for the low dielectric constant film. This allows providing further reduced specific dielectric constant of the film.

The interconnect structure 40 is formed in the circumference region of the semiconductor device 1. The circumference region is a region disposed in the outside of a region D1 for forming an electric circuit (region surrounded by dotted line in FIG. 1) having semiconductor devices such as transistors formed therein. The circumference region may preferably be a region apart from a dicing surface of the semiconductor device 1 by 100 μm or shorter. More specifically, the interconnect structure 40 may preferably be provided in a region apart from a dicing surface of the semiconductor device 1 by 100 μm or shorter. The circumference region is also provided with a seal ring 50 (guard ring), which surrounds the region D1 for forming an electric circuit. The interconnect structure 40 is provided outside of such seal ring 50.

The interconnect structure 40 is configured to include an electroconducting plug. The electroconducting plug is coupled to the diffusion layer 12 of the semiconductor substrate 10. The interconnect structure 40 extends through the interface of the interlayer insulating film 20 and the interlayer insulating film 30. The interconnect structure 40 is constituted as a via chain. Further, the via chain elongates over the substantially entire circumference of the region D1 for forming the electric circuit. However, such via chain includes a discontinuous spot, and is coupled to a pad 92 disposed in the region D1 for forming the electric circuit at such discontinuous spot. As shown in FIG. 5, the via chain (interconnect structure 40) is electrically coupled to the pad 92 through the diffusion layer 12. Meanwhile, the via chain is electrically isolated from the seal ring 50. Such configuration allows a measurement of the resistance of the interconnect structure 40 performed from the exterior of the semiconductor device 1.

An interlayer insulating film 72, an interlayer insulating film 74 and an interlayer insulating film 76 are sequentially deposited on the interlayer insulating film 30. In the present embodiment, materials of the respective interlayer insulating films 72, 74 and 76 are the above-described second insulating material.

Advantageous effects of the present embodiment will be described. In the semiconductor device 1, the interconnect structure 40 is provided in the circumference region disposed outside of the region D1 for forming the electric circuit. Further, such interconnect structure 40 extends through the interface of the interlayer insulating film 20 and the interlayer insulating film 30, which are formed of different insulating materials. Therefore, when a flaking-off is caused in such interface, which leads to causing a crack and a breaking in the interconnect structure 40, such flaking-off can be converted into changes in the electric characteristics. The changes in the electric characteristics typically indicate a change in a resistance or a change in a capacitance of the interconnect structure 40, or the like.

Therefore, even if flaking-off is caused in the above-described interface during the dicing process, such flaking-off can be detected with higher accuracy. Further, such detection is not limited to be performed before the dispatch of the product of the semiconductor device 1, and may be performed after the dispatch. Thus, a flaking-off created after the manufacture can also be detected, in addition to a flaking-off created during the manufacture (in case of dicing, in particular).

Further, the first and the second insulating materials have different dielectric constants. As such, in the interface between the interlayer insulating film having different dielectric constants (interlayer insulating film 20 and interlayer insulating film 30), a flaking-off is easily caused. Therefore, the semiconductor device 1 that is capable of detecting a flaking-off caused in such interface with higher accuracy is particularly useful.

When the first insulating material is silicon oxide and the second insulating material is a low dielectric constant material, a miniaturization in a patterning in the interlayer insulating film 20 and a reduction of a parasitic capacitance in the interlayer insulating film 30 can be balanced.

The interconnect structure 40 is constituted as a via chain. This allows achieving the interconnect structure 40 that elongates along the circumference of the region D1 for forming an electric circuit with a simple configuration. In particular this via chain elongates over the substantially entire circumference of the region D1 for forming the electric circuit. This allows detecting a flaking-off can be detected with higher accuracy, even if a flaking-off is caused in any location in the circumference of the region D1 for forming the electric circuit.

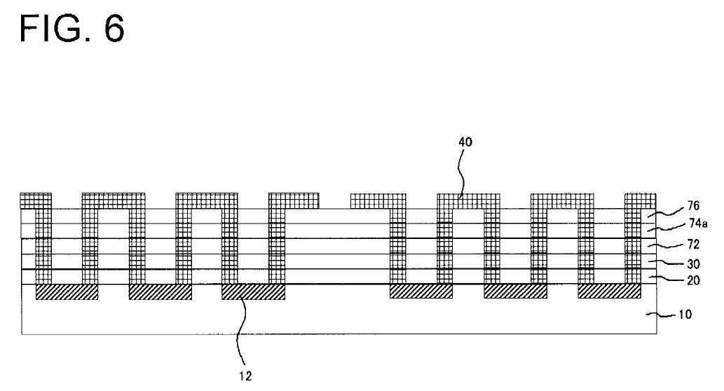

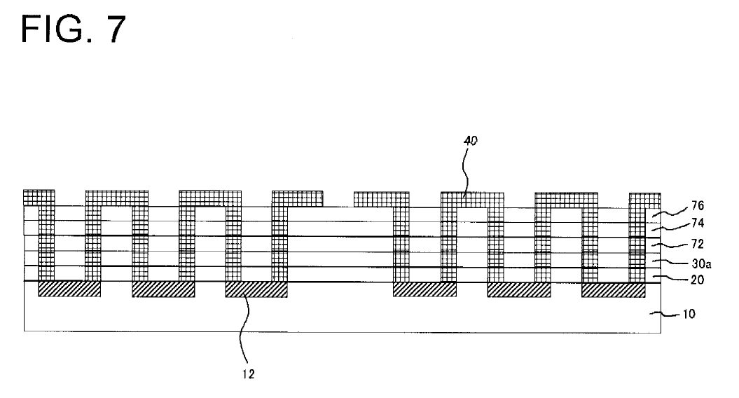

It is not intended that the semiconductor devices according to the present invention is limited to the configurations illustrated in the above-described embodiment, and various modifications thereof are available. Always describe the expansion of the invention. For example, the exemplary implementation, in which the first level interlayer insulating film 20 is formed of the first insulating material and the second to fifth interlayer insulating films 30, 72, 74 and 76 are formed with the second insulating material, has been illustrated in the above-described embodiment. Alternatively, as shown in FIG. 6, the interlayer insulating films 20 and 74a may be formed of the first insulating material and the interlayer insulating films 30, 72 and 76 may be formed of the second insulating material. In the diagram of FIG. 6, the interconnect structure 40 extends through all the interface of the interlayer insulating film 20 and the interlayer insulating film 30, the interface of the interlayer insulating film 72 and the interlayer insulating film 74a, and the interface of the interlayer insulating film 74a and the interlayer insulating film 76. Alternatively, as shown in FIG. 7, the interlayer insulating films 20 and 30a may be formed of the first insulating material and the interlayer insulating films 72, 74 and 76 may be formed of the second insulating material. In the diagram of FIG. 7, the interconnect structure 40 extends through the interface of the interlayer insulating film 30a and the interlayer insulating film 72.

The above-described exemplary implementations include the configuration, in which each of the interlayer insulating films (for example, interlayer insulating film 20) is a single layer. However, each of the interlayer insulating films may have a multiple-layered structure, which is composed of a plurality of insulating films formed of different insulating materials. It is also preferable that the interconnect structure 40 extends through interfaces between these insulating films in such case.

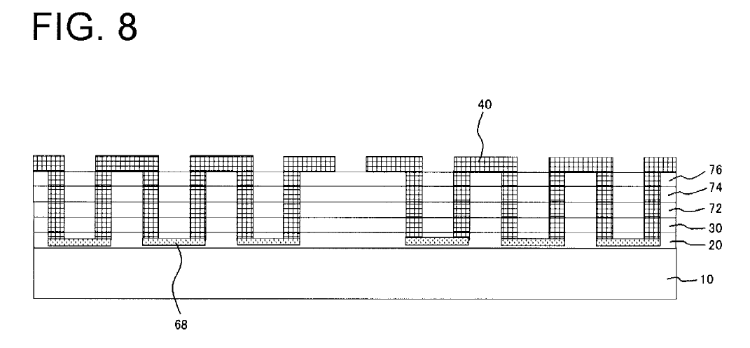

While the exemplary implementation in the above-described embodiment includes the configuration, in which the electroconducting plug constituting the interconnect structure 40 is coupled to the diffusion layer 12, the electroconducting plug may be coupled to the gate electrode 68, as shown in FIG. 8.

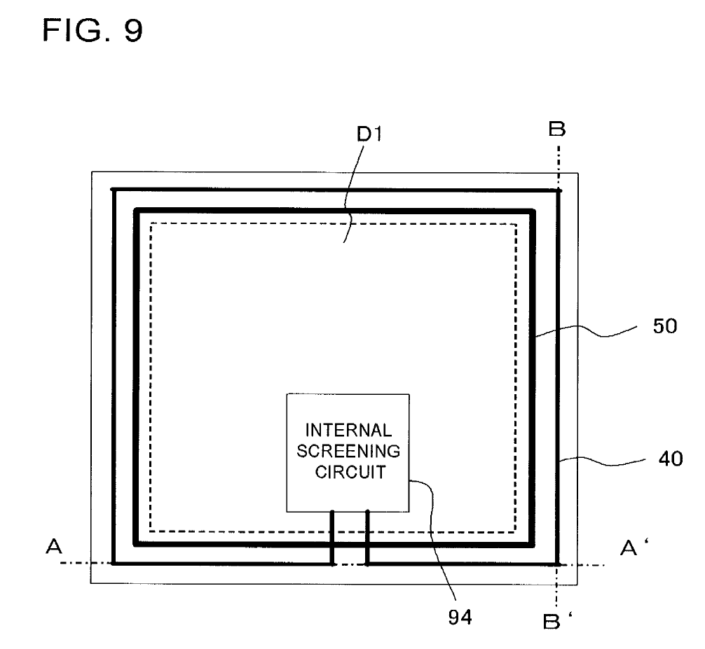

While the exemplary implementation in the above-described embodiment includes the configuration, in which the interconnect structure 40 is coupled to the pad 92, the interconnect structure 40 may be coupled to an internal screening circuit 94 formed in the region D1 for forming the electric circuit, as shown in FIG. 9. A coupling between the interconnect structure 40 and the internal screening circuit 94 is similar to the coupling between the interconnect structure 40 and the pad 92 as described in relation to FIG. 5. This internal screening circuit 94 functions as, for example, emitting a high (or low) signal if the resistance of the interconnect structure 40 is larger than a certain value due to a generation of a crack and/or a breaking, and otherwise emitting a low (or high) signal.

While the exemplary implementation in the above-described embodiment includes the configuration, in which the interconnect structure 40 is provided over the substantially entire circumference of the region D1 for forming an electric circuit, the interconnect structure 40 may alternatively be provided only in a portion of the circumference of the region D1 for forming an electric circuit. When the interconnect structure 40 is provided only in a portion of the circumference of the region D1 for forming an electric circuit, it is in particularly preferable to provide the interconnect structure in a corner section. While the exemplary implementation includes the configuration, in which the interconnect structure 40 is provided in the outside of the seal ring 50, the interconnect structure 40 may alternatively be provided in the inside of the seal ring 50, or in other words, between the region D1 for forming the electric circuit and the seal ring 50. However, it is not essential to provide the seal ring 50.

While the exemplary implementation in the above-described embodiment includes the configuration, in which employing different materials having different dielectric constants for the first and the second insulating materials, any combinations of materials may be employed for the first and the second insulating materials, provided that these are different types of insulating materials. For example, a combination of different low dielectric constant materials having different compositions may be employed. Alternatively, one of the first and the second insulating materials may be a material having carbon (C) in its molecular and the other may be a material having no carbon in its molecular. Since a flaking-off is easily created even in the interface of the interlayer insulating film having carbon in its molecular and the interlayer insulating film having no carbon in its molecular, the present invention, which allows detecting a flaking-off caused in such interface with higher accuracy, is particularly useful. It is apparent that the present invention is not limited to the above embodiment, and may be modified and changed without departing from the scope and spirit of the invention.

What is claimed is:

1. A semiconductor device having a region for forming an electric circuit, comprising:
a semiconductor substrate;
a first interlayer insulating film, provided on said semiconductor substrate and formed of a first insulating material;
a second interlayer insulating film, provided on said first interlayer insulating film and formed of a second insulating material, which is different from said first insulating material; and
an interconnect structure, provided in the outside of said region for forming an electric circuit and configured to include an electroconducting plug,
wherein said interconnect structure extends through an interface of said first interlayer insulating film and said second interlayer insulating film.

2. A semiconductor device as set forth in claim 1, wherein said first and said second insulating materials have different dielectric constants.

3. A semiconductor device as set forth in claim 1, wherein only one of said first and said second insulating materials has carbon in its molecular.

4. A semiconductor device as set forth in claim 1, wherein said first insulating material is silicon oxide, and said second insulating material is a low dielectric constant material.

5. A semiconductor device as set forth in claim 1, wherein said interconnect structure is provided in a region apart from a dicing surface of the semiconductor device by 100 μm or shorter.

6. A semiconductor device as set forth in claim 1, wherein said interconnect structure is constituted as a via chain elongating along a circumference of said region for forming an electric circuit.

7. A semiconductor device as set forth in claim 6, wherein said via chain elongates over the substantially entire circumference of said region for forming an electric circuit.

8. A semiconductor device as set forth in claim 1, further comprising a seal ring that surrounds said region for forming an electric circuit, wherein said interconnect structure is provided in the outside of said seal ring.

9. A semiconductor device as set forth in claim 1, wherein said electroconducting plug constituting said interconnect structure is coupled to a diffusion layer of said semiconductor substrate.

10. A semiconductor device as set forth in claim 1, wherein said electroconducting plug constituting said interconnect structure is coupled to a gate electrode disposed on said semiconductor substrate.

11. A semiconductor device as set forth in claim 6, wherein said via chain is provided in a portion of the circumference of said region for forming an electric circuit.

12. A semiconductor device as set forth in claim 11, wherein said portion of the circumference of said region for forming an electric circuit is a corner section of said circumference.
